(19) United States
(12) Patent Application Publication
(10) Pub. No.: US 2002/0008234 A1
(43) Pub. Date: Jan. 24, 2002

(54) Mixed-signal semiconductor structure, device including the structure, and methods of forming the device and the structure

(75) Inventors: Rudy M. Emrick, Gilbert, AZ (US); Keith V. Warble, Chandler, AZ (US)

Correspondence Address: MOTOROLA, INC., CORPORATE LAW DEPARTMENT - #56-238, 3102 NORTH 56TH STREET, PHOENIX, AZ, 85018, US

(73) Assignee: Motorola, Inc.

(21) Appl. No.: 09/840,213

(22) Filed: Apr. 23, 2001

Related U.S. Application Data
(63) Continuation-in-part of application No. 09/607,207, filed on Jun. 28, 2000.

(51) Int. Cl. H01L 29/12

(52) U.S. Cl. 257/43

(57) ABSTRACT

Mixed-signal devices (300) are formed using high quality epitaxial layers of monocrystalline materials grown overlying a monocrystalline substrate such as a large silicon wafer (302), using an accommodating buffer layer (304). The accommodating buffer layer (304) is a layer of monocrystalline oxide spaced apart from the silicon wafer by an amorphous interface layer of silicon oxide or an amorphous layer formed from a monocrystalline precursor. The device (300) includes passive components (314) formed away from the substrate (302), to minimize adverse signal interaction between passive component (314) signals and the substrate (302).

### CROSS REFERENCE TO RELATED APPLICATIONS

The present application is a continuation-in-part of U.S. patent application Ser. No. 09/607,207 entitled “Semiconductor Structure, Semiconductor Device, Communicating Device, Integrated Circuit, and Process for Fabricating the Same”, filed Jun. 28, 2000, by the assignee hereof.

### FIELD OF THE INVENTION

This invention relates generally to semiconductor structures and devices and to a method for their fabrication, and more specifically to mixed-signal semiconductor structures and devices and to the fabrication and use of semiconductor structures, devices, and integrated circuits that include a monocrystalline semiconductor layer formed overlying a monocrystalline substrate.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monocrystalline thin films on a foreign substrate such as silicon (Si). To achieve optimal characteristics of the various monocrystalline layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material. For example, mixed-signal devices could be formed using a compound semiconductor material to form radio frequency portions of the circuit and active devices such as transistors, digital devices, and the like could be formed using the silicon substrate.

Accordingly, a need exists for a semiconductor structure that provides a high quality monocrystalline film or layer over another monocrystalline material and for a process for making such a structure.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9A-9D illustrate schematically, in cross-section, the formation of a device structure in accordance with another embodiment of the invention;

FIGS. 10A-10D illustrate a probable molecular bonding structure of the device structures illustrated in FIGS. 9A-9D;

FIGS. 11-13 illustrate schematically, in cross-section, the formation of a device structure in accordance with still another embodiment of the invention;

FIGS. 14-15 illustrate schematically, in cross-section, device structures in accordance with another embodiment of the invention;

FIG. 16 illustrates schematically a communication device in accordance with an exemplary embodiment of the invention;

FIGS. 17-21 illustrate schematically, in cross section, the formation of the communication device of FIG. 16; and

FIG. 22 illustrates schematically, in cross section, a mixed-signal device structure in accordance with the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, an accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxides or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), gallium nitride (GaN), silicon carbide (SiC), and the like. However, monocrystalline material layer 26 may also comprise other semiconductor materials, metals, or insulators which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

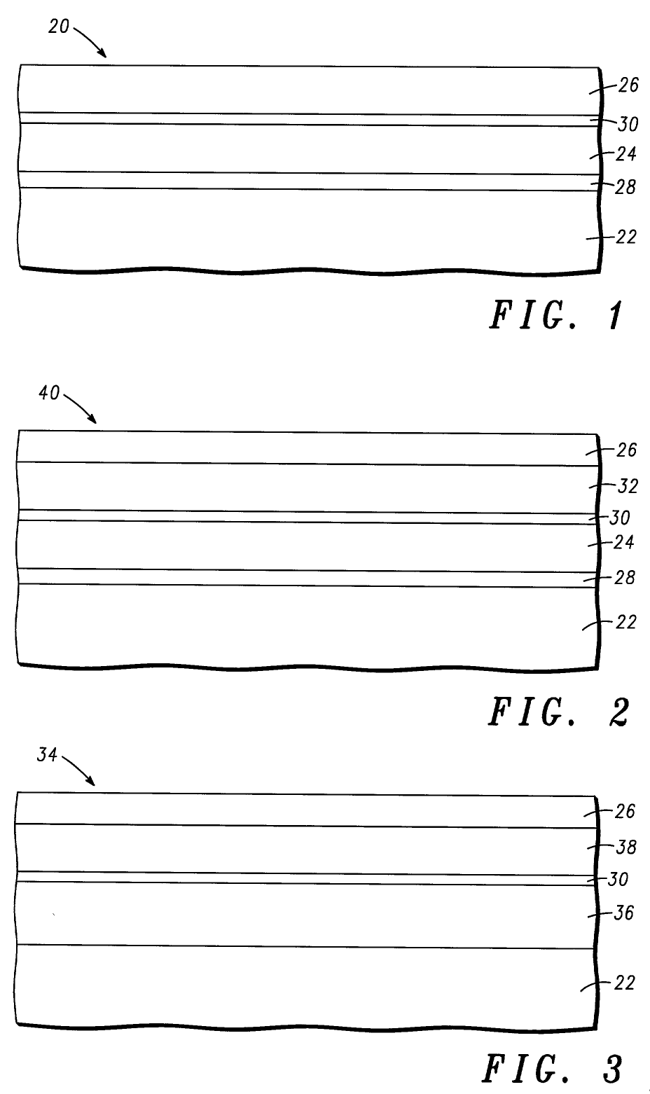

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z} TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the compound semiconductor layer from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700° C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for exanple, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The buffer layer preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z} TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered monocrystal with the crystalline orientation rotated by 45° with respect to the ordered 2×1 crystalline structure of the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

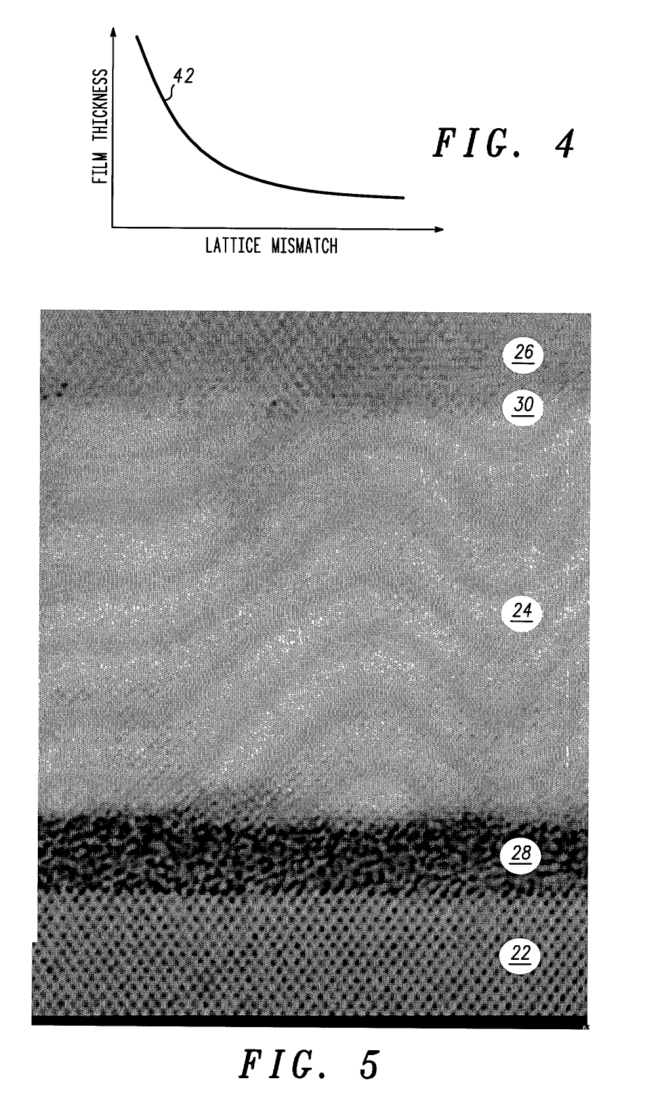

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

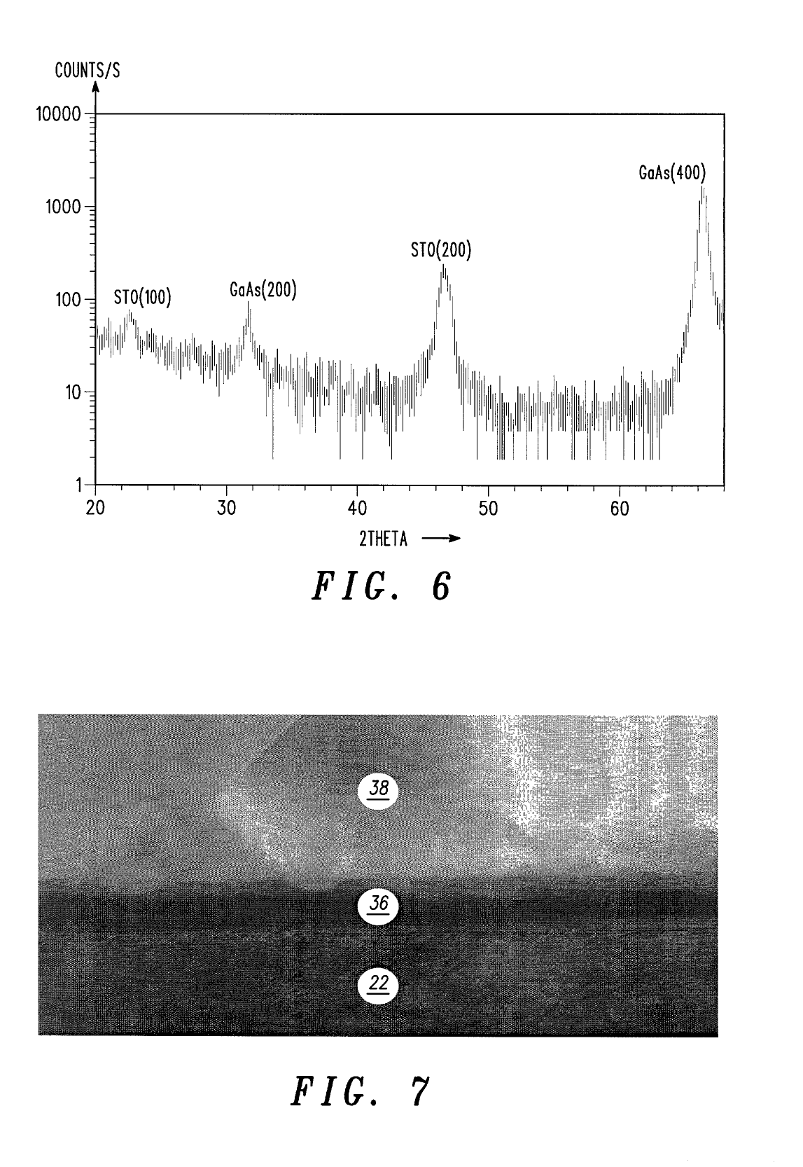

FIG. 6 illustrates an x-ray diffraction spectrum taken on a structure including monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The buffer layer is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In Accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, peroskite oxides such as alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

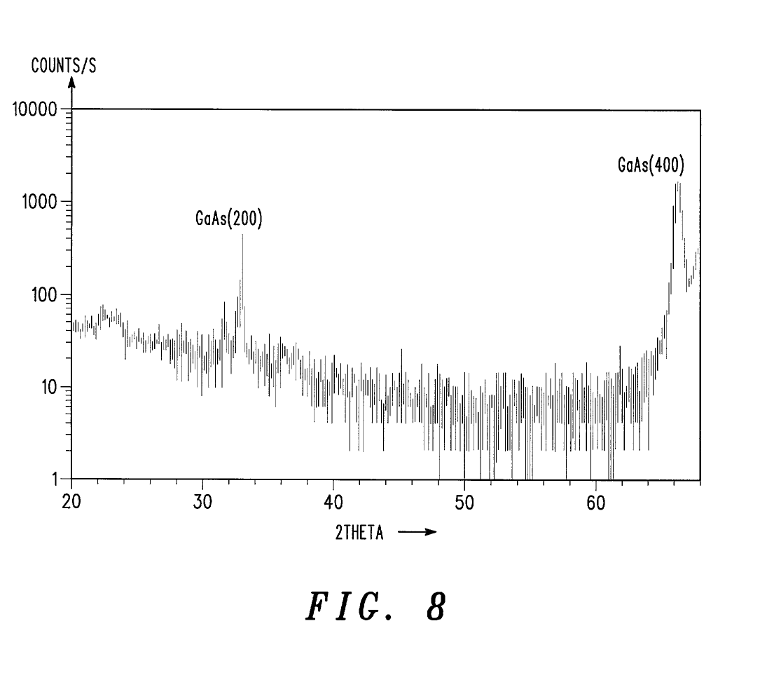

The formation of a device structure in accordance with another embodiment of the invention is illustrated schematically in cross-section in FIGS. 9A-9D. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9A-9D utilizes a template that includes a surfactant to facilitate layer-by-layer monocrystalline material growth.

Turning now to FIG. 9A, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium terminated surface represented in FIG. 9A by hatched line 55 which is followed by the addition of a template layer 60 which includes a surfactant layer 61 and capping layer 63 as illustrated in FIGS. 9B and 9C. Surfactant layer 61 may comprise, but is not limited to, elements such as Al, In and Ga, but will be dependent upon the composition of layer 54 and the overlying layer of monocrystalline material for optimal results. In one exemplary embodiment, aluminum is used for surfactant layer 61 and functions to modify the surface and surface energy of layer 54. Preferably, surfactant layer 61 is epitaxially grown, to a thickness of one to two monolayers, over layer 24 as illustrated in FIG. 9B by way of MBE, although other epitaxial processes may also be performed including CVD, MOCVD, MEE, ALE, PVD, CSD, PLD, or the like.

Surfactant layer 61 is then exposed to a gas such as arsenic, for example, to form capping layer 63 as illustrated in FIG. 9C. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, or the like to form the final structure illustrated in FIG. 9D.

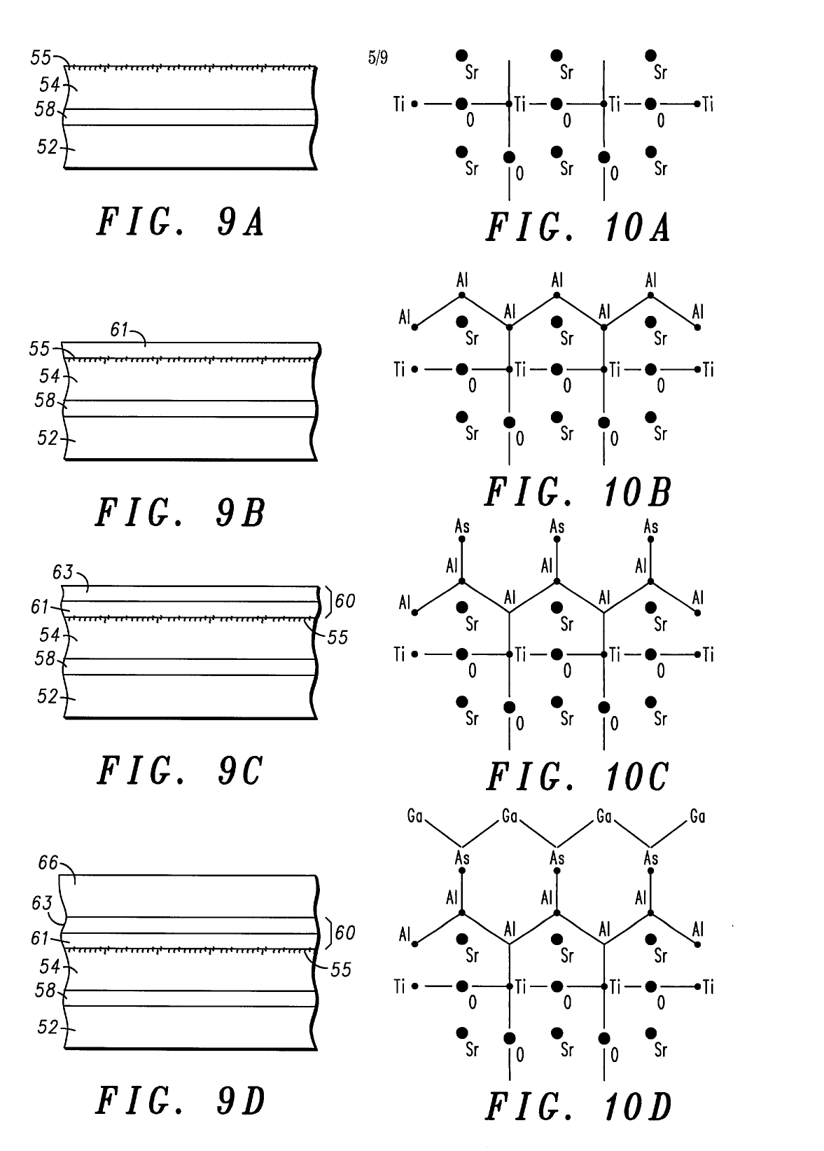

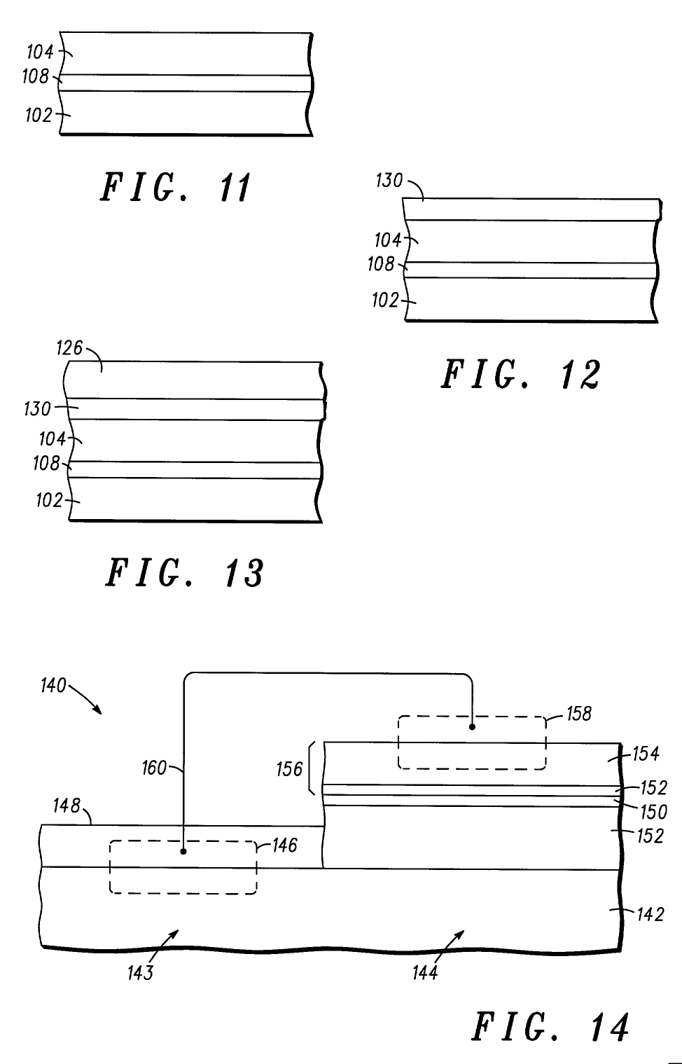

FIGS. 10A-10D illustrate possible molecular bond structures for a specific example of a compound semiconductor structure formed in accordance with the embodiment of the invention illustrated in FIGS. 9A-9D. More specifically, FIGS. 10A-10D illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 100 nm where the two-dimensional (2D) and three-dimensional (3D) growth shifts because of the surface energies involved. In order to maintain a true layer by layer growth (Frank Van der Merle growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, absent surface modification, a surfactant containing template was used, as described above with reference to FIGS. 9B-9D, to increase the surface energy of the monocrystalline oxide layer 54 and also to shift the crystalline structure of the template to a diamond-like structure that is in compliance with the original GaAs layer.

FIG. 10A illustrates the molecular bond structure of a strontium terminated surface of a strontium titanate monocrystalline oxide layer. An aluminum surfactant layer is deposited on top of the strontium terminated surface and bonds with that surface as illustrated in FIG. 10B, which reacts to form a capping layer comprising a monolayer of Al₂Sr having the molecular bond structure illustrated in FIG. 10B which forms a diamond-like structure with an sp³ hybrid terminated surface that is compliant with compound semiconductors such as GaAs. The structure is then exposed to As to form a layer of AlAs as shown in FIG. 10C. GaAs is then deposited to complete the molecular bond structure illustrated in FIG. 10D which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 24 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising germanium, for example, to form high efficiency photocells.

FIGS. 11-13 schematically illustrate, in cross-section, the formation of another embodiment of a device structure in accordance with the invention. This embodiment includes a compliant layer that functions as a transition layer that uses clathrate or Zint1 type bonding. More specifically, this embodiment utilizes an intermetallic template layer to reduce the surface energy of the interface between material layers thereby allowing for two dimensional layer by layer growth.

The structure illustrated in FIG. 11 includes a monocrystalline substrate 102, an amorphous interface layer 108 and an accommodating buffer layer 104. Amorphous intermediate layer 108 is grown on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2 but preferably comprises silicon oxide. Substrate 102 is preferably silicon but may also comprise any of those materials previously described with reference to substrate 22 in FIGS. 1-3, and accommodating buffer layer is preferably a strontium barium titanate layer, but may include any of the materials described above in connection with layer 24 in FIGS. 1-2.

A template layer 130 is deposited over accommodating buffer layer 104 as illustrated in FIG. 12 and preferably comprises a thin layer of Zint1 type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of about one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga, (Ca,Sr,Eu,Yb)In₂, BaGe₂As, and SrSn₂As₂.

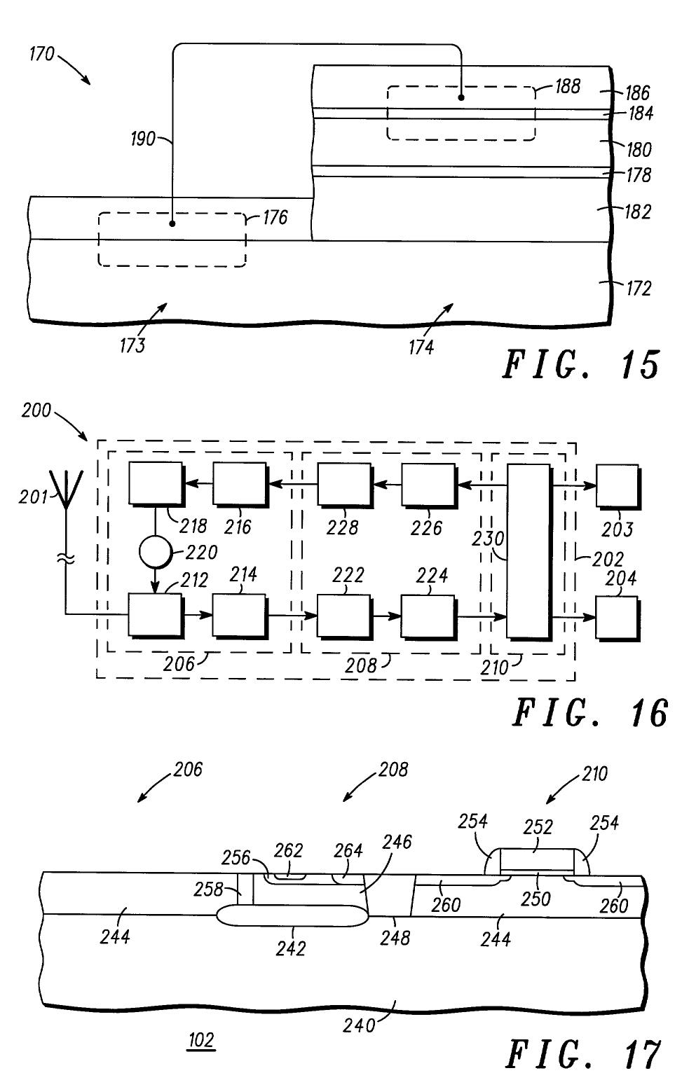

A monocrystalline material layer 126 is epitaxially grown over template layer 130 to achieve the final structure illustrated in FIG. 13. As a specific example, an SrAl₂ layer may be used as template layer 130 and an appropriate monocrystalline material layer 126 such as a compound semiconductor material GaAs is grown over the SrAl₂. The Al-Ti (from the accommodating buffer layer of layer of Sr_{z}Ba_{1-z}TiO₃ where z ranges from 0 to 1) bond is mostly metallic while the Al-As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

FIG. 14 illustrates schematically, in cross section, a device structure 140 in accordance with a further embodiment of the invention. Device structure 140 includes a monocrystalline semiconductor substrate 142, preferably a monocrystalline silicon wafer. Monocrystalline semiconductor substrate 142 includes two regions, 143 and 144. An electrical semiconductor component generally indicated by the dashed line 146 is formed, at least partially, in region 143. Electrical component 146 can be a resistor, a capacitor, an active semiconductor component such as a diode or a transistor or an integrated circuit such as a CMOS or bipolar integrated circuit. For example, electrical semiconductor component 146 can be a CMOS integrated circuit configured to perform digital signal processing or another function for which silicon integrated circuits are well suited. The electrical semiconductor component in region 143 can be formed by conventional semiconductor processing as well known and widely practiced in the semiconductor industry. A layer of insulating material 148 such as a layer of silicon dioxide or the like may overlie electrical semiconductor component 146.

Insulating material 148 and any other layers that may have been formed or deposited during the processing of semiconductor component 146 in region 143 are removed from the surface of region 144 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 144 and is reacted with the oxidized surface to form a first template layer (not shown). In accordance with one embodiment of the invention a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form the monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 144 to form an amorphous layer of silicon oxide on the second region and at the interface between the silicon substrate and the monocrystalline oxide.

In accordance with an embodiment of the invention, the step of depositing the monocrystalline oxide layer is terminated by depositing a second template layer 150, which can be 1-10 monolayers of titanium, barium, strontium, barium and oxygen, titanium and oxygen, or strontium and oxygen. A layer 152 of a monocrystalline semiconductor material is then deposited overlying the second template layer by a process of molecular beam epitaxy. The deposition of layer 152 may be initiated by depositing a layer of arsenic onto the template. This initial step is followed by depositing gallium and arsenic to form monocrystalline gallium arsenide.

In accordance with one aspect of the present embodiment, after semiconductor layer 150 formation, the monocrystalline titanate layer and the silicon oxide layer, which is interposed between substrate 142 and the titanate layer, are exposed to an anneal process such that the titanate and oxide layers form an amorphous oxide layer 152. An additional compound semiconductor layer 154 is then epitaxially grown over layer 152, using the techniques described above in connection with layer 152, to form compound semiconductor layer 156. Alternatively, the above described anneal process can be performed after formation of additional compound semiconductor layer 154.

In accordance with a further embodiment of the invention, a semiconductor component, generally indicated by a dashed line 158 is formed, at least partially, in compound semiconductor layer 154. Semiconductor component 158 can be formed by processing steps conventionally used in the fabrication of gallium arsenide or other III-V compound semiconductor material devices. Semiconductor component 158 can be any active or passive component, and preferably is a semiconductor laser, an electromagnetic radiation (e.g., light-infra red to ultra violet radiation) emitting device, an electromagnetic radiation detector such as a photodetector, a heterojunction bipolar transistor (HBT), a high frequency MESFET, or another component that utilizes and takes advantage of the physical properties of compound semiconductor materials. A metallic conductor schematically indicated by the line 160 can be formed to electrically couple device 158 and device 146, thus implementing an integrated device that includes at least one component formed in the silicon substrate and one device formed in the monocrystalline compound semiconductor material layer. Although illustrative structure 140 has been described as a structure formed on a silicon substrate 144 and having a barium (or strontium) titanate layer and a gallium arsenide layer 154, similar devices can be fabricated using other monocrystalline substrates, oxide layers and other monocrystalline compound semiconductor layers as described elsewhere in this disclosure.

FIG. 15 illustrates a semiconductor structure 170 in accordance with a further embodiment of the invention. Structure 170 includes a monocrystalline semiconductor substrate 172 such as a monocrystalline silicon wafer that includes a region 173 and a region 174. An electrical component schematically illustrated by the dashed line 176 is formed in region 173 using conventional silicon device processing techniques commonly used in the semiconductor industry. Using process steps similar to those described above, a monocrystalline oxide layer and an intermediate amorphous silicon oxide layer are formed overlying region 174 of substrate 172. A template layer 178 and subsequently a monocrystalline semiconductor layer 180 are formed overlying the monocrystalline oxide layer. An amorphous oxide layer 182 is then formed by exposing the monocrystalline oxide and silicon oxide films to an anneal process. In accordance with a further embodiment of the invention, an additional monocrystalline oxide layer 184 is formed overlying layer 180 by process steps similar to those used to form the monocrystalline oxide material described above, and an additional monocrystalline semiconductor layer 186 is formed overlying monocrystalline oxide layer 184 by process steps similar to those used to form layer 180. Monocrystalline oxide layer 184 may desirably be exposed to an additional anneal process to cause the material to become amorphous. However, in accordance with various aspects of this embodiment, layer 184 retains its monocrystalline form. In accordance with one embodiment of the invention, at least one of layers 180 and 186 are formed from a compound semiconductor material.

A semiconductor component generally indicated by a dashed line 188 is formed at least partially in monocrystalline semiconductor layer 180. In accordance with one embodiment of the invention, semiconductor component 188 may include a field effect transistor having a gate dielectric formed, in part, by monocrystalline oxide layer 184. In addition, monocrystalline semiconductor layer 186 can be used to implement the gate electrode of that field effect transistor. In accordance with one embodiment of the invention, monocrystalline semiconductor layer 180 is formed from a group III-V compound and semiconductor component 188 is a radio frequency amplifier that takes advantage of the high mobility characteristic of group III-V component materials. In accordance with yet a further embodiment of the invention, an electrical interconnection schematically illustrated by the line 190 electrically interconnects component 176 and component 188. Structure 170 thus integrates components that take advantage of the unique properties of the two monocrystalline semiconductor materials.

By way of more specific examples, other integrated circuits and systems are illustrated in FIGS. 16-21. FIG. 16 includes a simplified block diagram illustrating a portion of a communicating device 200 having a signal transceiving means 201, an integrated circuit 202, an output unit 203, and an input unit 204. Examples of the signal transceiving means include an antenna, a modem, or any other means by which information or data can be sent either to or from an external unit. As used herein, transceiving is used to denote that the signal transceiving means may be capable of only receiving, only transmitting, or both receiving and transmitting signals from or to the communicating device. Output unit 203 can include a display, a monitor, a speaker, or the like. The input unit can include a microphone, a keyboard, or the like. Note that in alternative embodiments the output unit 203 and input unit 204 could be replaced by a single unit such as a memory or the like. The memory can include random access memory or nonvolatile memory, such as a hard disk, a flash memory card or module, or the like.

An integrated circuit is generally a combination of at least two circuit elements (e.g., transistors, diodes, resistors, capacitors, and the like) inseparably associated on or within a continuous substrate. Exemplary integrated circuit 202 includes a compound semiconductor portion 206, a bipolar portion 208 and an MOS portion 210. Compound semiconductor portion 206 includes electrical components that are formed at least partially within a compound semiconductor material. Transistors and other electrical components within the compound semiconductor portion 206 are capable of processing signals at radio frequencies of at least approximately 0.8 GHz. In other embodiments, the signals could be at lower or higher frequencies. For example, some materials, such as indium gallium arsenide, are capable of processing signals at radio frequency signals at approximately 27 GHz.

Compound semiconductor portion 206 further includes a duplexer 212, a radio frequency-to-baseband converter 214 (demodulating means or demodulating circuit), baseband-to-radio frequency converter 216 (modulating means or modulating circuit), a power amplifier 218, and an isolator 220. The bipolar portion 208 and the MOS portion 210 typically are formed in a Group IV semiconductive material. Bipolar portion 208 includes a receiving amplifier 222, an analog-to-digital converter 224, a digital-to-analog converter 226, and a transmitting amplifier 228. MOS portion 210 includes a digital signal processing means 230. An example of such means includes any one of the commonly available DSP cores available in the market, such as the Motorola DSP 566xx (from Motorola, Incorporated of Schaumburg, Ill.) and Texas Instruments TMS 320C54x (from Texas Instruments of Dallas, Tex.) families of digital signal processors. This digital signal processing means typically includes complementary MOS (CMOS) transistors and analog-to-digital and digital-to-analog converters. Clearly, other electrical components are present in the integrated circuit 202.

In one mode of operation, the communicating device 200 receives a signal from an antenna, which is part of the signal transceiving means 201. The signal passes through the duplexer 212 to the radio frequency-to-baseband converter 214. The analog data or other information is amplified by receiving amplifier 222 and transmitted to the digital signal processing means 230. After the digital signal processing means 230 has processed the information or other data, the processed information or other data is transmitted to the output unit 203. If the communicating device is a pager, the output unit can be a display. If the communicating device is a cellular telephone, the output unit 203 can include a speaker, a display, or both.

Data or other information can be sent through the communicating device 200 in the opposite direction. The data or other information will come in through the input unit 204. In a cellular telephone, this could include a microphone or a keypad. The information or other data is then processed using the digital signal processing means 230. After processing, the signal is then converted using the digital-to-analog converter 226. The converted signal is amplified by the transmitting amplifier 228. The amplified signal is modulated by the baseband-to-radio frequency converter 216 and further amplified by power amplifier 218. The amplified RF signal passes through the isolator 220 and duplexer 212 to the antenna.

Prior art embodiments of the communicating device 200 would have at least two separate integrated circuits: one for the compound semiconductor portion 206 and one for the MOS portion 210. Bipolar portion 208 may be on the same integrated circuit as MOS portion 210 or could be on still another integrated circuit. With an embodiment of the present invention, all three portions can now be formed within a single integrated circuit. Because all of the transistors can reside on a single integrated circuit, the communicating device can be greatly miniaturized and allow for greater portability of a communicating device.

Attention is now directed to a method for forming exemplary portions of the integrated circuit 202 as illustrated in FIGS. 17-21. In FIG. 17, a p-type doped, monocrystalline silicon substrate 240 is provided having a compound semiconductor portion 206, a bipolar portion 208, and an MOS portion 210. Within the bipolar portion, the monocrystalline silicon substrate is doped to form an N⁺ buried region 242. A lightly p-type doped epitaxial monocrystalline silicon layer 244 is then formed over the buried region 242 and substrate 240. A doping step is then performed to create a lightly n-type doped drift region 246 above the N⁻ buried region 242. The doping step converts the dopant type of the lightly p-type epitaxial layer within a section of the bipolar region 208 to a lightly doped n-type monocrystalline silicon region. A field isolation region 248 is then formed between the bipolar portion 208 and the MOS portion 210. A gate dielectric layer 250 is formed over a portion of the epitaxial layer 244 within MOS portion 210, and the gate electrode 252 is then formed over the gate dielectric layer 250. Sidewall spacers 254 are formed along vertical sides of gate electrode 252 and gate dielectric layer 250.

A p-type dopant is introduced into the drift region 246 to form an active or intrinsic base region 256. An n-type, deep collector region 258 is then formed within the bipolar portion 208 to allow electrical connection to the buried region 242. Selective n-type doping is performed to form N⁺ doped regions 260 and the emitter region 262. N⁺ doped regions 260 are formed within layer 244 along adjacent sides of the gate electrode 252 and are source, drain, or source/drain regions for the MOS transistor. The N⁺ doped regions 260 and emitter region 262 have a doping concentration of at least 1E19 atoms per cubic centimeter to allow ohmic contacts to be formed. A p-type doped region is formed to create the inactive or extrinsic base region 264 which is a P⁺ doped region (doping concentration of at least 1E19 atoms per cubic centimeter).

In the embodiment illustrated in FIG. 17, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 210, and a vertical NPN bipolar transistor has been formed within the bipolar portion 208. As of this point, no circuitry has been formed within the compound semiconductor portion 206.

All of the layers that have been formed during the processing of the bipolar and MOS portions of the integrated circuit are now removed from the surface of compound semiconductor portion 206. A bare silicon surface is thus provided for the subsequent processing of this portion, for example in the manner set forth above.

An accommodating buffer layer 266 is then formed over the substrate 240 as illustrated in FIG. 18. The accommodating buffer layer will initially form as a monocrystalline layer over the properly prepared (i.e., having the appropriate template layer) bare silicon surface in portion 206 and will eventually form an amorphous oxide layer as described herein. The portion of layer 266 that forms over portions 208 and 210, however, may be polycrystalline or amorphous because it is formed over a material that is not monocrystalline, and therefore, does not nucleate monocrystalline growth. The accommodating buffer layer 266 typically is a monocrystalline metal oxide or nitride layer and typically has a thickness in a range of approximately 2-100 nm. In one particular embodiment, the accommodating buffer layer is approximately 5-15 nm thick. During the formation of the accommodating buffer layer, an amorphous intermediate layer 268 is formed along the uppermost silicon surfaces of the integrated circuit 202. This amorphous intermediate layer 268 typically includes an oxide of silicon and has a thickness and range of approximately 1-5 nm. In one particular embodiment, the thickness is approximately 2 nm. Following the formation of accommodating buffer layer 266 and amorphous intermediate layer 268, a template layer 270 is then formed and has a thickness in a range of approximately one to ten monolayers of a material. In one particular embodiment, the material includes titanium-arsenic, strontium-oxygen-arsenic, or other similar materials as previously described with respect to FIGS. 1-3.

A monocrystalline compound semiconductor layer 272 is then epitaxially grown overlying the monocrystalline portion of accommodating buffer layer 266 as shown in FIG. 19. The portion of layer 272 that is grown over portions of layer 266 that are not monocrystalline may be polycrystalline or amorphous. The monocrystalline compound semiconductor layer can be formed by a number of methods and typically includes a material such as germanium, gallium arsenide, aluminum gallium arsenide, indium phosphide, or other compounds semiconductor materials as previously mentioned. The thickness of the layer is in a range of approximately 1-5,000 nm, and more preferably 100-500 nm. In this particular embodiment, each of the elements within the template layer are also present in the accommodating buffer layer 266, the monocrystalline compound semiconductor material 272, or both. Therefore, the delineation between the template layer 270 and its two immediately adjacent layers disappears during processing. Therefore, when a transmission electron microscopy (TEM) photograph is taken, an interface between the accommodating buffer layer 266 and the monocrystalline compound semiconductor layer 272 is seen.

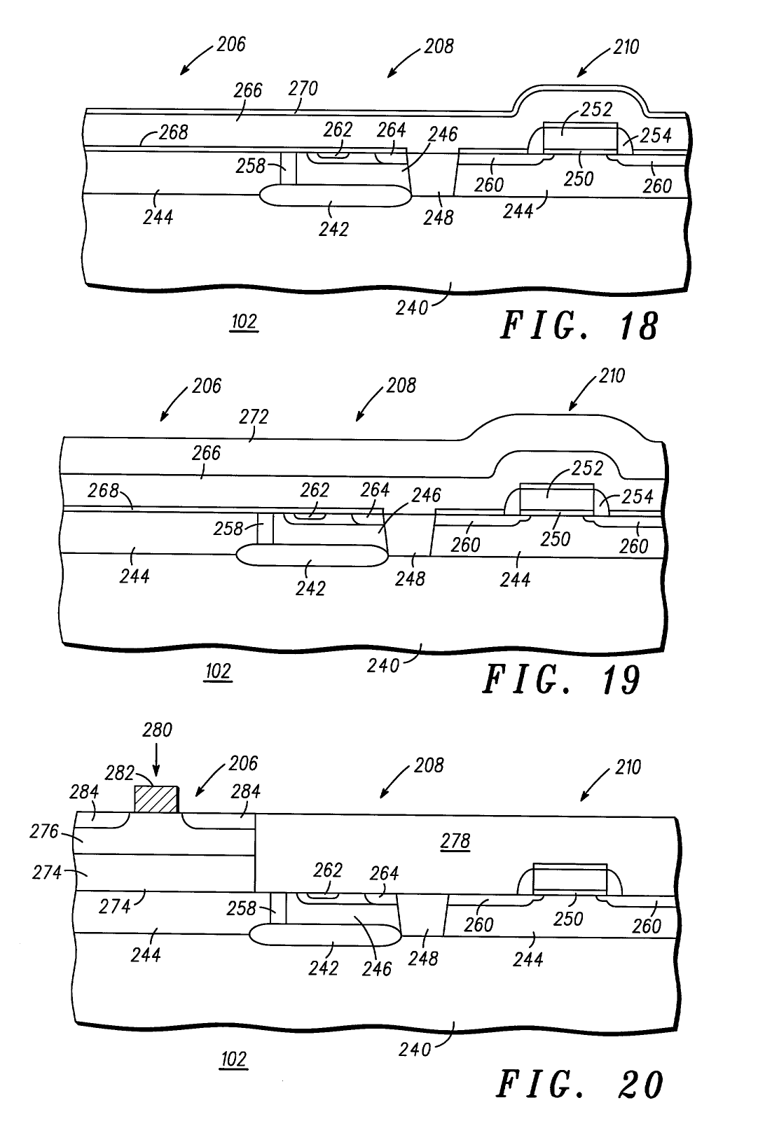

Next, an amorphous oxide layer 274 is formed by exposing amorphous oxide layer 268 and accommodating buffer layer 266 to an anneal process. Either before or after the anneal process, additional semiconductor material can be deposited onto compound semiconductor layer 272 to form compound semiconductor layer 276, as illustrated in FIG. 20.

At this point in time, sections of compound semiconductor layer 276 and amorphous oxide layer 274 are removed from portions overlying the bipolar portion 208 and the MOS portion 210. In accordance with an alternate aspect of this embodiment, the anneal process may suitably be performed after portions of layers 268 and/or 274 have been removed. After the sections are removed, an insulating layer 278 is then formed over the substrate 240. Insulating layer 278 can include a number of materials such as oxides, nitrides, oxynitrides, low-k dielectrics, or the like. As used herein, low-k is a material having a dielectric constant no higher than approximately 3.5. After insulating layer 278 has been deposited, it is then polished, removing portions of insulating layer 278 that overlie monocrystalline compound semiconductor layer 276.

A transistor 280 is then formed within monocrystalline compound semiconductor portion 206 by forming a gate electrode 282 on monocrystalline compound semiconductor layer 276 and doped regions 284 within the monocrystalline compound semiconductor layer 276. In this embodiment, the transistor 280 is a metal semiconductor field-effect transistor (MESFET). If the MESFET is an n-type MESFET, doped regions 284 and monocrystalline compound semiconductor layer 276 are also n-type doped. If a p-type MESFET were to be formed, then doped regions 284 and monocrystalline compound semiconductor layer 276. would have just the opposite doping type. The heavier doped (N⁺) regions 284 allow ohmic contacts to be made to the monocrystalline compound semiconductor layer 276. At this point in time, the active devices within the integrated circuit have been formed. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 206, 208, and 210.

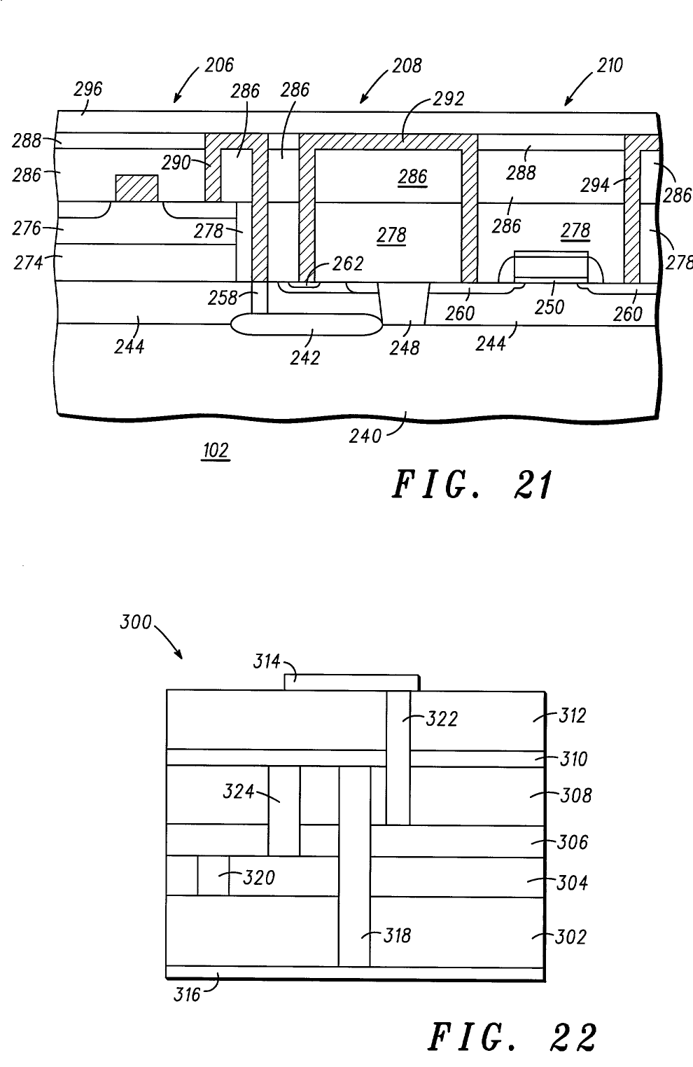

Processing continues to form a substantially completed integrated circuit 202 as illustrated in FIG. 21. An insulating layer 286 is formed over the substrate 240. Insulating layer 286 may include an etch-stop or polish-stop region that is not illustrated in FIG. 21. A second insulating layer 288 is then formed over the first insulating layer 286. Portions of layers 288, 286, 278, and 274 are removed to define contact openings where the devices are to be interconnected. Interconnect trenches are formed within insulating layer 288 to provide the lateral connections between the contacts. As illustrated in FIG. 21, interconnect 290 connects a source or drain region of the n-type MESFET within portion 206 to the deep collector region 258 of the NPN transistor within the bipolar portion 208. Emitter region 262 of the NPN transistor is connected to one of the doped regions 260 of the n-channel MOS transistor within the MOS portion 210 via an interconnect 292. The other doped region 260 is electrically connected to other portions of the integrated circuit that are not shown via an interconnect 294.

A passivation layer 296 is formed over the interconnects 290, 292, and 294 and insulating layer 288. Other electrical connections are made to the transistors as illustrated as well as to other electrical or electronic components within the integrated circuit 202 but are not illustrated in the figures. Further, additional insulating layers and interconnects may be formed as necessary to form the proper interconnections between the various components within the integrated circuit 202.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion into the compound semiconductor portion 206 or the MOS portion 210. More specifically, turning to the embodiment as described with respect to FIG. 16, the amplifiers 228 and 222 may be moved over to the compound semiconductor portion 206, and the converters 224 and 226 can be moved over into the MOS portion 210. Therefore, the requirement of special fabricating steps solely used for making a bipolar transistor can be eliminated. Therefore, there would only be a compound semiconductor portion and a MOS portion to the integrated circuit.

FIG. 22 illustrates a portion of a mixed-signal device 300 in accordance with yet another embodiment of the invention. Device 300 is similar to device 280, illustrated in FIG. 20, except that device 300 includes additional passive components formed away from the substrate. As noted above, forming passive components away from the substrate reduces signal loss and signal attenuation due to signal interactions with the substrate.

Device 300 includes a monocrystalline substrate 302, formed of, for example silicon; an accommodating buffer layer 304, such as the accommodating buffer layer described above in connection with FIGS. 1-3; a monocrystalline semiconductor layer such as a compound semiconductor layer 306; a first insulating layer 308; ground plane layers 310 and 316; a second insulating layer 312; and a passive component 314. Substrate 302 and layers 304-306 may be formed of materials described above in connection with substrate 22 and layers 24, 28, 36, and 26 illustrated in FIGS. 1-3.

Passive component 314 may include any component used in the formation of mixed-signal devices. For example, component 314 may include a transmission line (microstrip, coplanar waveguide, or stripline), a resistor, a capacitor, an inductor, a waveguide, and the like. Furthermore, although not illustrated, multiple passive components may be coupled to each other.

Layers 308 and 312 of device 300 may comprise any insulating material used in the fabrication of semiconductor components, and preferably includes a low-loss dielectric material such as polyimide or paralene and is preferably about 10 μm thick.

Ground plane 310 is formed of formed of a conductive material layer. In accordance with one aspect of this embodiment layer 310 is formed of a metal such as gold or gold alloy and is about 5 μm thick. Although device 300 is illustrated with ground plane layer 310 interposed between insulating layers 308 and 312, other structures in accordance with alternate embodiments of the invention may include a ground plane formed above transmission line 314. Such a ground plane may be in addition to or in lieu of layer 310.

Structure 300 formation is similar to circuit 202 formation described above. In particular, layers 302 and 306 may be formed using the method described above in connection with forming accommodating buffer layer 274 and semiconductor layer 276. Furthermore, structure 300 may be integrated with MOS and/or bipolar devices formed at least partially within substrate 302.

After semiconductor layer 306 is formed overlying substrate 302, a low-loss dielectric material such as polyimide or paralene is applied to the surface of layer 306, using for example, spin-on deposition techniques. Next, ground plane layer 310 is formed by depositing conductive material using for example CVD or PVD techniques, and if desired, patterning the conductive material. A second insulating layer is then formed overlying the ground plane, using for example the same process used to form layer 308. A passive component may be formed overlying second insulating layer 212 using deposition and etch, chemical mechanical polishing, or other suitable techniques. Finally, ground plane layer 316 may be formed, using for example, the same method used to form layer 310.

Various components of device 300 may be coupled together using conductive features such as conductive plugs 318-324. As illustrated, conductive plug 318 couples ground plane layer 310 to ground plane 316 formed on a back side of substrate 302. Other layers of device 300 may be similarly interconnected using other conductive features. For example, active device region 306 may be coupled to a device formed within substrate 302 using conductive feature 320, as described above in connection with FIGS. 14-21, and passive component 314 may be coupled to active device layer 306 using conductive feature 322, which is suitably insulated from layer 310. Similarly, a device or a portion of a device formed using layer 306 may be coupled to ground plane layer 310 using a conducive feature 324.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline substrate;
an accommodating buffer layer formed overlying the monocrystalline substrate;
a semiconductor layer formed over the accommodating buffer layer;
a first insulating layer formed over the semiconductor layer; and
a passive component formed overlying the insulating layer.

2. The semiconductor structure of claim 1, wherein the passive component comprises a transmission line.

3. The semiconductor structure of claim 2, wherein the transmission line is a microstrip transmission line.

4. The semiconductor structure of claim 2, wherein the transmission line is a coplanar transmission line.

5. The semiconductor structure of claim 2, wherein the transmission line is a stripline.

6. The semiconductor structure of claim 1, wherein the passive component comprises a transmission line.

7. The semiconductor structure of claim 1, wherein the first insulating layer comprises a material selected from the group consisting of polyimide material and paralene material.

8. The semiconductor structure of claim 1, further comprising a second insulating layer interposed between the first insulating layer and the passive component.

9. The semiconductor structure of claim 8, wherein the second insulating layer comprises a material selected from the group consisting of polyimide material and paralene material.

10. The semiconductor structure of claim 1, further comprising a first ground plane coupled to the semiconductor layer.

11. The semiconductor structure of claim 10, wherein the first ground plane is formed above the first insulating layer.

12. The semiconductor structure of claim 10, wherein the first ground plane is adjacent the monocrystalline substrate.

13. The semiconductor structure of claim 10, further comprising a second ground plane coupled to the first ground plane.

14. The semiconductor structure of claim 1, further comprising a conductive feature coupled to the monocrystalline substrate and the semiconductor layer.

15. The semiconductor structure of claim 1, further comprising a conductive feature coupled to the passive component and the semiconductor layer.

16. The semiconductor structure of claim 1, wherein the accommodating buffer layer is monocrystalline.

17. The semiconductor structure of claim 16, further comprising an amorphous interface layer interposed between the monocrystalline substrate and the accommodating buffer layer.

18. The semiconductor structure of claim 17, wherein the amorphous interface comprises silicon oxide.

19. The semiconductor structure of claim 1, wherein the accommodating buffer layer is amorphous.

20. The semiconductor structure of claim 1, wherein the accommodating buffer layer comprises a material selected from the group consisting of alkaline earth metal titanates, alkaline earth metal zirconates, alkaline earth metal hafniates, alkaline earth metal tantalates, alkaline earth metal ruthenates, and alkaline earth metal niobates.

21. The semiconductor structure of claim 20, wherein the accommodating buffer layer comprises SrₓBa₁₋ₓTiO₃, where x ranges from 0 to 1.

22. The semiconductor structure of claim 1, wherein the accommodating buffer layer comprises an oxide formed as a monocrystalline oxide and subsequently heat treated to convert the monocrystalline oxide to an amorphous oxide.

23. The semiconductor structure of claim 1, wherein the monocrystalline substrate comprises silicon.

24. The semiconductor structure of claim 1, wherein the accommodating buffer layer has a thickness of about 2-10 nm.

25. The semiconductor structure of claim 1, wherein the semiconductor layer comprises a material selected from the group consisting of III-V compounds, mixed III-V compounds, II-VI compounds, and mixed II-VI compounds.

26. The semiconductor structure of claim 1, wherein the semiconductor layer comprises a material selected from the group consisting of GaAs, AlGaAs, InP, InGaAs, InGaP, ZnSe, GaN, SiC and ZnSeS.

27. The semiconductor structure of claim 1, further comprising an active device formed at least partially in semiconductor layer.

28. The semiconductor structure of claim 27, wherein the active device includes a radio frequency device.

29. The semiconductor structure of claim 1, further comprising an active device formed at least partially in the monocrystalline substrate.

30. A monolithic microwave integrated circuit formed using the structure of claim 1.

31. A semiconductor structure comprising:
a monocrystalline semiconductor substrate;
an accommodating buffer layer overlying the monocrystalline semiconductor substrate;
a monocrystalline compound semiconductor layer formed overlying the accommodating buffer layer;
a first insulating layer overlying the monocrystalline compound semiconductor layer; and
a passive device formed overlying the first insulating layer.

32. The semiconductor structure of claim 31, further comprising a second insulating layer.

33. The semiconductor structure of claim 32, wherein the second insulating layer comprises a material selected from the group consisting of polyimide material and paralene material.

34. The semiconductor structure of claim 31, wherein the first insulating layer comprises a material selected from the group consisting of polyimide material and paralene material.

35. The semiconductor structure of claim 31, further comprising an electronic device formed at least partially in the monocrystalline semiconductor substrate.

36. The semiconductor structure of claim 35, wherein the electronic device includes a bipolar transistor.

37. The semiconductor structure of claim 35, wherein the electronic device includes a field effect transistor.

38. The semiconductor structure of claim 31, further comprising an electronic device formed at least partially within the monocrystalline compound semiconductor layer.

39. The semiconductor structure of claim 38, wherein the electronic device includes a high frequency field effect transistor.

40. The semiconductor structure of claim 31, wherein the monocrystalline compound semiconductor layer comprises a material selected from the group consisting of GaAs, AlGaAs, InP, InGaAs, InGaP, ZnSe, GaN, SiC, and ZnSeS.

41. The semiconductor structure of claim 31, wherein the accommodating buffer layer comprises a material selected from the group consisting of alkaline earth metal titanates, alkaline earth metal zirconates, alkaline earth metal hafniates, alkaline earth metal tantalates, alkaline earth metal ruthenates, and alkaline earth metal niobates.

42. The semiconductor structure of claim 31, wherein the monocrystalline semiconductor substrate comprises silicon.

43. The semiconductor structure of claim 42, wherein the monocrystalline semiconductor substrate consists essentially of silicon.

44. The semiconductor structure of claim 31, wherein the accommodating buffer layer is monocrystalline.

45. The semiconductor structure of claim 44, further comprising an amorphous interface layer interposed between the monocrystalline semiconductor substrate and the accommodating buffer layer.

46. The semiconductor structure of claim 31, wherein the accommodating buffer layer is amorphous.

47. The semiconductor structure of claim 31, wherein the passive component includes a transmission line.

48. The semiconductor structure of claim 47, wherein the transmission line includes a microstrip.

49. The semiconductor structure of claim 47, wherein the transmission line includes a stripline.

50. The semiconductor structure of claim 47, wherein the transmission line includes a coplanar transmission line.

51. The semiconductor structure of claim 31, wherein the passive component includes a waveguide.

52. A process for fabricating a semiconductor structure comprising the steps of:
providing a monocrystalline substrate;
epitaxially growing a monocrystalline accommodating buffer layer overlying the monocrystalline substrate;
forming an amorphous interface layer between the monocrystalline substrate and the monocrystalline accommodating buffer layer;
epitaxially growing a monocrystalline compound semiconductor layer overlying the monocrystalline accommodating buffer layer; and
forming a passive device overlying the monocrystalline compound semiconductor layer.

53. The process of claim 52, further comprising the step of annealing the monocrystalline accommodating buffer layer to convert the monocrystalline accommodating buffer layer to an amorphous layer.

54. The process of claim 52, further comprising the step of forming a first insulating layer overlying the monocrystalline compound semiconductor layer.

55. The process of claim 54, further comprising the step of forming a ground plane layer overlying the first insulating layer.

56. The process of claim 55, further comprising the step of forming a second insulting layer between the ground plane and the passive device.

57. The process of claim 52, further comprising forming a ground plane.

58. The process of claim 52, wherein the step of providing comprises providing a substrate comprising silicon.

59. The process of claim 52, wherein the step of epitaxially growing includes forming a layer comprising gallium arsenide.

60. The process of claim 52, wherein the step of forming a passive device includes forming a transmission line.

61. The process of claim 60, wherein the step of forming a transmission line includes forming a microstrip.

62. The process of claim 60, wherein the step of forming a transmission line includes forming a coplanar transmission line.

63. The process of claim 60, wherein the step of forming a transmission line includes forming a stripline.

64. The process of claim 52, wherein the step of forming a passive device includes forming a waveguide.
